(19) United States
(12) Patent Application Publication
(10) Pub. No.: US 2026/0321317 A1
(43) Pub. Date: Oct. 15, 2026

(54) SEMICONDUCTOR DEVICE AND CONTROL METHOD THEREOF, COMPUTING IN MEMORY APPARATUS AND MEMORY SYSTEM

(71) Applicant: CCSH Corporation, Wuhan (CN)

(72) Inventors: Lei Jin, Wuhan (CN); Zongliang Huo, Wuhan (CN); Xinran Li, Wuhan (CN); Yu Zhang, Wuhan (CN); Feng Xu, Wuhan (CN); Yuanyuan Min, Wuhan (CN); Ziye Zhang, Wuhan (CN); Wendong Wang, Wuhan (CN)

(73) Assignee: CCSH Corporation, Wuhan (CN)

(21) Appl. No.: 19/358,169

(22) Filed: Oct. 14, 2025

(30) Foreign Application Priority Data
Apr. 14, 2025 (CN) 202510466397.1

(51) Int. Cl. G11C 16/26; G11C 16/04; G11C 16/08; G11C 16/10

(52) U.S. Cl. CPC G11C 16/26; G11C 16/0483; G11C 16/08; G11C 16/102

(57) ABSTRACT

A semiconductor device is provided. The semiconductor device may include a memory cell array including a plurality of memory strings. One memory string may include a plurality of first memory cells and a plurality of second memory cells coupled. Word lines coupled to the plurality of second memory cells may include a first and second portion of word lines. The semiconductor device may include a peripheral circuit configured to apply a first read voltage to a word line coupled to one first memory cell of the plurality of first memory cells, apply a first pass voltage to the first portion of word lines, and apply a second pass voltage to the second portion of word lines after performing a program operation on the plurality of first memory cells. The peripheral circuit may acquire a current on a signal line coupled to one end of the memory string.

### CROSS-REFERENCE TO RELATED APPLICATIONS

This application claims the benefit of priority to Chinese Application No. 202510466397.1, filed on Apr. 14, 2025, which is hereby incorporated by reference in its entirety.

### TECHNICAL FIELD

Examples of the present disclosure relate to a computer information technology, and relate to, but not limited to, a semiconductor device and a control method thereof, a computing in memory apparatus and a memory system.

### BACKGROUND

In the classical von Neumann computing architecture, the memory is separate from the processor, and the data is transmitted through the data bus. When executing the command, the processor first reads the data from the memory, and then writes the updated data back into the memory after being processed, and the frequent data transfer brings huge power consumption and time overheads; in addition, since the bandwidth of the memory is limited, the processing speed of the processor is limited by the access speed of the memory, which greatly affects the computing performance. With the development of the computing in memory architecture, the processing of massive data requires higher and higher accuracy of the reading data of the memory cell array.

### SUMMARY

According to one aspect of the present disclosure, a semiconductor device is provided. The semiconductor device may include a memory cell array including a plurality of memory strings. One memory string of the plurality of memory strings may include a plurality of first memory cells and a plurality of second memory cells coupled, and word lines coupled to the plurality of second memory cells may include a first portion of word lines and a second portion of word lines. The semiconductor device may include a peripheral circuit. The peripheral circuit may be configured to apply a first read voltage to a word line coupled to one first memory cell of the plurality of first memory cells, apply a first pass voltage to the first portion of word lines, and apply a second pass voltage to the second portion of word lines after performing a program operation on the plurality of first memory cells. The second pass voltage may be different from the first pass voltage. The peripheral circuit may be configured to acquire a current on a signal line coupled to one end of the memory string. The current on the memory string may be within a target current range.

In some implementations, the plurality of second memory cells of the plurality of memory strings may be configured to have a program state and an erase state. In some implementations, in the first portion of word lines, a ratio of a number of the second memory cells in the erase state to a number of memory cells in the program state may be a first ratio. In some implementations, in the second portion of word lines, a ratio of the number of the second memory cells in the erase state to the number of the second memory cells in the program state may be a second ratio. In some implementations, the first ratio may be greater than the second ratio, and the first pass voltage may be less than the second pass voltage.

In some implementations, the word lines coupled to the plurality of second memory cells may further include a third portion to an N-th portion. In some implementations, N may be a positive integer greater than or equal to 3. In some implementations, the peripheral circuit may be configured to apply different pass voltages to different portions of word lines.

In some implementations, in a plurality of portions of the word lines, a portion of word lines with a larger ratio of the number of the second memory cells in the erase state to the number of the second memory cells in the program state may be applied with a smaller pass voltage.

In some implementations, in different portions of word lines, ratios of a number of the second memory cells in an erase state to the number of the second memory cells in a program state may be different.

In some implementations, the peripheral circuit may be configured to perform a program operation on at least part of the second memory cells in an erase state on the memory string in response to the current on the memory string not being within the target current range.

In some implementations, a program state of the second memory cells may include a plurality of threshold voltage levels in successive different threshold voltage ranges. In some implementations, the peripheral circuit may be configured to program threshold voltage levels of different second memory cells on the memory string to be different.

In some implementations, the peripheral circuit may be configured to apply the first pass voltage to the first portion of word lines, and apply the second pass voltage to the second portion of word lines. In some implementations, after performing a program operation on at least part of the second memory cells on the memory string, the current on the memory string may be within the target current range. In some implementations, the peripheral circuit may be configured to perform a program operation on at least part of the second memory cells on the memory string, after applying the first pass voltage to the first portion of word lines, and applying the second pass voltage to the second portion of word lines, the current on the memory string may be within the target current range.

In some implementations, the peripheral circuit may be configured to apply a first sub-pass voltage to the first portion of word lines, and apply a second sub-pass voltage to the second portion of word lines in response to the current on the memory string not being within the target current range. In some implementations, the second sub-pass voltage may be different from the second pass voltage, and the first sub-pass voltage may be different from the first pass voltage.

In some implementations, the peripheral circuit may be configured to apply a second read voltage to a word line coupled to one first memory cell of the plurality of first memory cells of the memory string, apply a pass voltage in a case of a current being within the target current range to the first portion of word lines, and apply a pass voltage in a case of a current being within the target current range to the second portion of word lines, in response to the current on the memory string being within the target current range. In some implementations, the peripheral circuit may be configured to acquire the current on the signal line coupled to the one end of the memory string to obtain analog computing information.

In some implementations, the peripheral circuit may be configured to, during a period of applying a second read voltage to a word line coupled to the one first memory cell of the first memory cells of the memory string, apply a first turn-on voltage to word lines coupled to remaining first memory cells of the first memory cells, and apply a second turn-on voltage to a top select gate line coupled to the memory string, to acquire the current on the signal line coupled to the one end of the memory string.

In some implementations, a signal line coupled to one end of the memory string may include a common source line or a bit line.

According to another aspect of the present disclosure, a memory apparatus is provided. The memory apparatus may include one or more semiconductor devices. The one or more semiconductor device may include a memory cell array including a plurality of memory strings. One memory string of the plurality of memory strings may include a plurality of first memory cells and a plurality of second memory cells coupled, and word lines coupled to the plurality of second memory cells include a first portion of word lines and a second portion of word lines. The memory apparatus may include a peripheral circuit. The peripheral circuit may be configured to apply a first read voltage to a word line coupled to one first memory cell of the plurality of first memory cells, apply a first pass voltage to the first portion of word lines, and apply a second pass voltage to the second portion of word lines after performing a program operation on the plurality of first memory cells. The second pass voltage may be different from the first pass voltage. The peripheral circuit may be configured to acquire a current on a signal line coupled to one end of the memory string. The current on the memory string may be within a target current range. The semiconductor device may be configured to perform a first operation on weight information and input data to obtain analog computing information. The memory apparatus may include a processing circuit coupled to the semiconductor device. The processing circuit may be configured to determine an operation result based on the analog computing information.

In some implementations, the processing circuit may include a control circuit coupled to the semiconductor device. In some implementations, the control circuit may be configured to control the semiconductor device to perform the first operation. In some implementations, the processing circuit may include an analog-to-digital conversion circuit coupled to the semiconductor device. In some implementations, the analog-to-digital conversion circuit may be configured to convert the analog computing information into digital information. In some implementations, the processing circuit may include a data processing circuit coupled to the analog-to-digital conversion circuit. In some implementations, the data processing circuit may be configured to perform a second operation on the digital information to determine the operation result.

According to a further aspect of the present disclosure, a method of controlling a semiconductor device is provided. The method may include applying a first read voltage to a word line coupled to one first memory cell of a plurality of first memory cells of a memory string, applying a first pass voltage to a first portion of word lines, and applying a second pass voltage to a second portion of word lines after performing a program operation on the plurality of first memory cells. The second pass voltage may be different from the first pass voltage. The method may include acquiring a current on a signal line coupled to one end of the memory string. The current on the memory string may be within a target current range. The semiconductor device may include a memory cell array including a plurality of memory strings. One memory string of the plurality of memory strings may include a plurality of first memory cells and a plurality of second memory cells connected. Word lines coupled to the plurality of second memory cells may include the first portion of word lines and the second portion of word lines.

In some implementations, the plurality of second memory cells of the plurality of memory strings may be configured to have a program state and an erase state. In some implementations, the method may further include acquiring a ratio of a number of the second memory cells in the erase state to the number of the second memory cells in the program state in the first portion of word lines that is a first ratio. In some implementations, the method may further include acquiring a ratio of the number of the second memory cells in the erase state to the number of the second memory cells in the program state in the second portion of word lines that is a second ratio. In some implementations, the method may further include applying the first pass voltage to the first portion of word lines, and applying the second pass voltage to the second portion of word lines. In some implementations, the first ratio may be greater than the second ratio, and the first pass voltage may be less than the second pass voltage.

In some implementations, the word lines coupled to the plurality of second memory cells may further include a third portion to an N-th portion. In some implementations, N may be a positive integer greater than or equal to 3. In some implementations, the method may include applying different pass voltages to different portions of word lines.

In some implementations, the method may include performing a program operation on at least part of the second memory cells in an erase state on the memory string in response to the current on the memory string not being within the target current range. In some implementations, in different portions of word lines, ratios of a number of the second memory cells in the erase state to the number of the second memory cells in a program state may be different.

In some implementations, the method may include applying a second read voltage to a word line coupled to one first memory cell of the plurality of first memory cells of the memory string, keeping applying a pass voltage in a case of a current being within the target current range to the first portion of word lines, and keeping applying a pass voltage in a case of a current being within the target current range to the second portion of word lines, in response to the current on the memory string being within the target current range. In some implementations, the method may include acquiring the current on the signal line coupled to the one end of the memory string to obtain analog computing information.

In some implementations, the method may include, during a period of applying a second read voltage to a word line coupled to the one first memory cell of the first memory cells of the memory string, applying a first turn-on voltage to word lines coupled to remaining first memory cells of the first memory cells, and applying a second turn-on voltage to a top select gate line coupled to the memory string, to acquire the current on the signal line coupled to the one end of the memory string.

According to yet another aspect of the present disclosure, a memory system configured to perform one or more of the operations described herein is provided.

The method of controlling the semiconductor device is utilized for driving the semiconductor device provided by any one of the above examples. The beneficial effects of the control method of the semiconductor device are the same as the beneficial effects of the semiconductor device provided by any one of the above examples, and details are not described herein again.

### BRIEF DESCRIPTION OF THE DRAWINGS

In the drawings, like reference numbers may describe similar components in different views. Like reference numbers with different letter suffixes may represent different examples of similar components. The drawings generally illustrate various examples discussed herein by way of example and not limitation.

FIG. 1 is a schematic structural diagram of a computing in memory apparatus according to an example of the present disclosure;

FIG. 2 is a schematic structural diagram of a processing circuit of a computing in memory apparatus according to an example of the present disclosure;

FIG. 3 is a schematic structural diagram of a peripheral circuit of a semiconductor device according to an example of the present disclosure;

FIG. 4 is a first schematic structural diagram of a semiconductor device according to an example of the present disclosure;

FIG. 5 is a second schematic structural diagram of a semiconductor device according to an example of the present disclosure;

FIG. 6 is a first schematic structural diagram of a memory cell array according to an example of the present disclosure;

FIG. 7 is a second schematic structural diagram of a memory cell array according to an example of the present disclosure;

FIG. 8 is a third schematic structural diagram of a memory cell array according to an example of the present disclosure;

FIG. 9 is a schematic timing diagram of a process for compensating a memory string current according to an example of the present disclosure;

FIG. 10 is a first schematic diagram of current variation of adjacent memory strings of a memory cell array according to an example of the present disclosure;

FIG. 11 is a second schematic diagram of current variation of adjacent memory strings of a memory cell array according to an example of the present disclosure;

FIG. 12 is a first schematic diagram of a memory state of a second memory cell in a memory cell array according to an example of the present disclosure;

FIG. 13 is a second schematic diagram of a memory state of a second memory cell of a memory cell array according to an example of the present disclosure;

FIG. 14 is a third schematic diagram of a memory state of a second memory cell of a memory cell array according to an example of the present disclosure;

FIG. 15 is a schematic structural diagram of a memory system according to an example of the present disclosure;

FIG. 16 is a schematic structural diagram of an electronic device according to an example of the present disclosure;

FIG. 17 is a schematic structural diagram of a storage medium of a memory system according to an example of the present disclosure;

FIG. 18 is a first schematic flow diagram of a control method of a semiconductor device according to an example of the present disclosure;

FIG. 19 is a second schematic flow diagram of a control method of a semiconductor device according to an example of the present disclosure;

FIG. 20 is a third schematic flow diagram of a control method of a semiconductor device according to an example of the present disclosure;

FIG. 21 is a fourth schematic flow diagram of a control method of a semiconductor device according to an example of the present disclosure; and

FIG. 22 is a fifth schematic flow diagram of a control method of a semiconductor device according to an example of the present disclosure.

### DETAILED DESCRIPTION

The technical solutions of the present disclosure are further described in detail below with reference to the drawings and specific examples.

In the examples of the present disclosure, the terms “first,” “second,” and the like are used to distinguish similar objects, and are not used to describe a specific order or sequence.

In the examples of the present disclosure, the term “A is in contact with B ” includes a case where A and B are in direct contact, or a case where other components are interposed between the A and B, and A is in indirect contact with B.

It should be understood that “some examples” mentioned throughout the specification means that specific features, structures, or characteristics related to the examples are included in at least one example of the present disclosure. Thus, “in some examples” appearing throughout the specification need not necessarily refer to the same example. Further, these particular features, structures, or characteristics may be incorporated in one or more examples in any suitable manner. It should be understood that, in various examples of the present disclosure, the sequence numbers of the foregoing processes do not mean a sequence of execution sequences. An execution sequence of each process should be determined by the function and the intrinsic logic thereof. The sequence numbers of the foregoing processes should not constitute any limitation on an implementation process of the examples of the present disclosure. The foregoing sequence numbers of the examples of the present disclosure are merely for description, and do not represent the advantages and disadvantages of the examples.

It should be noted that, in this specification, the terms “including,” “comprising,” or any other variant thereof are intended to cover a non-exclusive inclusion, such that a process, method, article, or apparatus that includes a series of elements includes not only those elements but also other elements not explicitly listed, or elements inherent to such processes, methods, articles, or apparatuses. Without further restriction, the elements defined by the statement “include one” do not preclude the presence of additional identical elements in the process, method, article, or apparatus that includes the element.

It is to be understood that the meaning of “on,” “over,” and “above” in the present disclosure should be interpreted in a broadest manner such that “on” not only indicates its “on” something and there is no intervening feature or layer therebetween (i.e., directly on something), but also includes the meaning of “on” something and there are intervening features or layers therebetween.

It should be noted that although the present specification is described in terms of examples, not every example includes only one independent technical solution, and this description of the specification is merely for the sake of clarity, and those skilled in the art should use the specification as a whole, and the technical solutions in the examples may also be combined appropriately to form other examples that can be understood by those skilled in the art.

With the development of in-memory computation architecture, in an in-memory computation memory, by modifying an in-memory computation architecture of a “read” circuit, an operation result may be obtained directly from the “read” circuit (in a subsequent example, an example of “inference operation” is used as an example to distinguish from a “read operation” in a non-in-memory computation process), and a result is “written” back to a target address of the memory, thereby avoiding frequently transferring data between a traditional memory and a CPU, and reducing overhead caused by unnecessary data transfer. In this way, not only the power consumption is greatly reduced (for example, the power consumption of the data transfer is reduced to 1/10-1/100 of the total power consumption), but also the memory can be used for logic computation to improve the computing power, thereby significantly improving the computation efficiency. This puts a higher requirement on the accuracy (computational accuracy) of the read current of the in-memory computation memory.

It can be understood that, in a process of reading data (current) of memory cells in different memory strings in a scenario where the memory only serves as a device for storing data, the difference in the degrees of influences of physical structures of memory cells in different memory strings (for example, a resistance value of a channel structure of a memory cell) on determining data of one memory cell in different memory strings is relatively small. The influence on the precision of the read data can also be ignored. However, in an in-memory computation memory, a quantity of memory cells participating in computation (for example, a memory cell represented as an open state) in one memory string needs to be determined by a final current size flowing through the memory string. If the difference between the resistance values of the physical structures of the memory cells in different memory strings is relatively large, representing that the difference between the resistance values of different memory strings is larger when taking the memory string as a whole. Consequently, there is an error in the determined quantity of memory cells participating in computation in one memory string, resulting in an error in the computation result, and the performance of the in-memory computation memory is reduced.

For example, due to the large difference between the resistance values of the physical structures of the memory cells in different memory strings (for example, the resistance values of the channel structures of the memory cells), the erase effects of different memory strings are different under the drive of the current in the erase state. For example, data in some memory cells may not be completely erased, or some memory cells are excessively erased, resulting in a deviation in the threshold voltage distribution of the memory cells. In this way, in the case where the data is written and read in the erased memory block, the error of the read data is easily caused, and the reading accuracy is affected.

To overcome these and other challenges, the present disclosure provides a semiconductor device, a method of controlling thereof, and a computing in memory apparatus (also referred to herein as simply “memory apparatus”), which can reduce the deviation of the current of the memory string or reduce the current difference between adjacent memory strings and improve the accuracy of the in-memory computation.

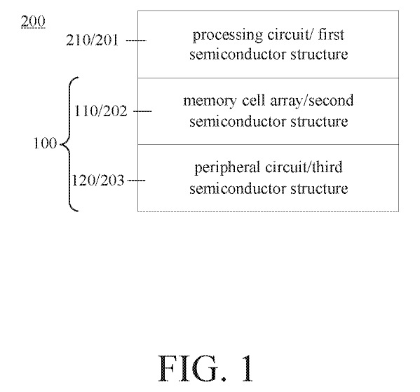

In some examples, as shown in FIG. 1, the present disclosure provides a computing in memory apparatus 200. For example, the computing in memory apparatus 200 may include, but is not limited to, one or more of a NAND flash memory (for example, a vertical NAND flash memory), a NOR flash memory, a dynamic random access memory (DRAM), a ferroelectric random access memory (FRAM), a magnetic random access memory (MRAM), a phase change random access memory (PCRAM), a resistive random access memory (RRAM), and a nanometer random access memory (NRAM).

In some examples, as shown in FIG. 1, the computing in memory apparatus 200 includes: one or more semiconductor devices 100 and a processing circuit 210. The processing circuit 210 and the semiconductor device 100 may be connected by bonding.

The semiconductor device 100 is configured to perform a first operation on weight information and input data to obtain analog computing information.

The processing circuit 210 is coupled to the semiconductor device 100. The processing circuit 210 is configured to determine an operation result based on the analog computing information.

As an example, the processing circuit 210 and the semiconductor device 100 are in different planes and stacked on each other. Also, a memory cell array 110 and a peripheral circuit 120 in the semiconductor device 100 may be in different planes and stacked on each other, so that the planar size of the semiconductor device 100 may be reduced.

For example, as shown in FIG. 1, the processing circuit 210 and the semiconductor device 100 may be formed in parallel on different semiconductor structures. For example, the processing circuit 210 is formed on the first semiconductor structure 201, the memory cell array 110 is formed on the second semiconductor structure 202, and the peripheral circuit 120 is formed on the third semiconductor structure 203. Various bonding techniques such as hybrid bonding, transfer bonding, and the like are then used to stack them on each other.

The examples provided in the present disclosure may vertically integrate the processing circuit 210 and the semiconductor device 100, and vertically separate the processing circuit 210, the memory cell array 110, and the peripheral circuit 120 into different planes, which may reduce the chip size and increase the memory density.

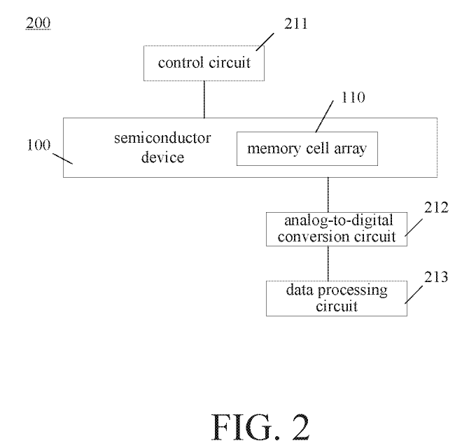

In some examples, as shown in FIG. 2, the processing circuit 210 includes a control circuit 211, an analog-to-digital conversion circuit 212, and a data processing circuit 213.

The control circuit 211 is coupled to the semiconductor device 100. The control circuit 211 is configured to control the semiconductor device 100 to perform a first operation.

The analog-to-digital conversion circuit 212 is coupled to the semiconductor device 100 and is configured to convert the analog computing information into digital information. For example, the analog-to-digital conversion circuit 212 may include an analog-to-digital converter.

The data processing circuit 213 is coupled to the analog-to-digital conversion circuit 212 and is configured to perform a second operation on the digital information to determine an operation result. As an example, the data processing circuit 213 includes, but is not limited to, a CPU, a GPU, a digital signal processor (DSP), a tensor processing unit (TPU), a visual processing unit (VPU), a neural processing unit (NPU), a synergistic processing unit (SPU), a physics processing unit (PPU), and an image signal processor (ISP). In an example, the data processing circuit 213 may be an NPU. The NPU may perform operations such as arithmetic/logical operations, rotation and shift operations, compensation operations, activation operations and pooling operations, and the like.

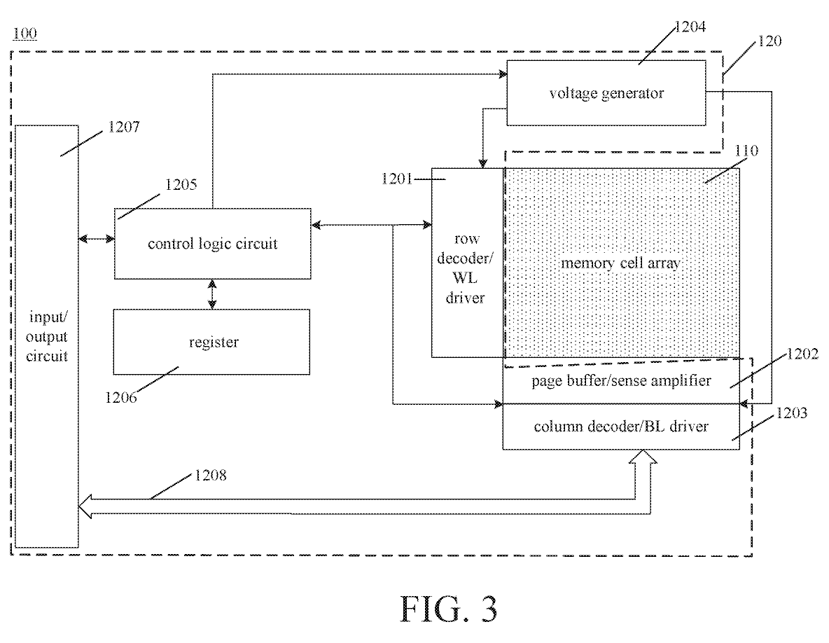

In some examples, as shown in FIG. 3, the peripheral circuit 120 includes various types of circuit structures formed using metal-oxide-semiconductor (MOS) transistors. For example, as shown in FIG. 3, the peripheral circuit 120 may include a plurality of circuit structures such as a row decoder/word line driver 1201, a page buffer (PB)/sense amplifier 1202, a column decoder/bit line driver 1203, a voltage generator 1204, a control logic circuit 1205, a register 1206, an input/output circuit 1207, a data bus 1208, and the like.

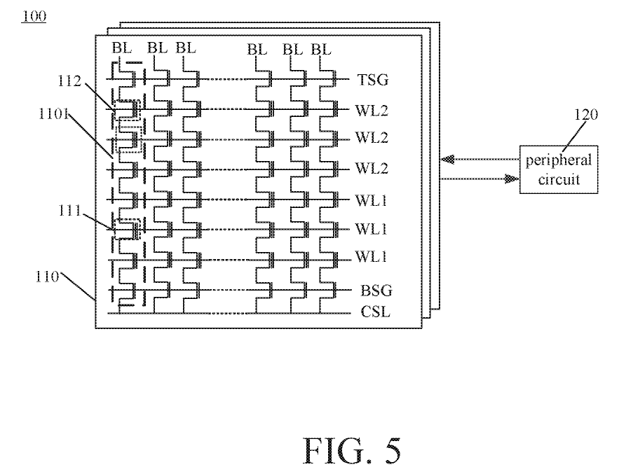

As shown in FIG. 5, the peripheral circuit 120 may be coupled to the memory cell array 110 through a bit line (BL), a word line (WL), a source line, a source select gate (SSG), and a drain select gate (DSG). The peripheral circuit 120 is configured to implement logical operations (e.g., program, read, or write operations) of the memory cell array 110 by applying a voltage signal and/or a current signal to each target memory cell and sensing a voltage signal and/or a current signal from each target memory cell via a bit line BL, a word line WL, a source SL, a source select gate SSG or a drain select gate DSG, or the like.

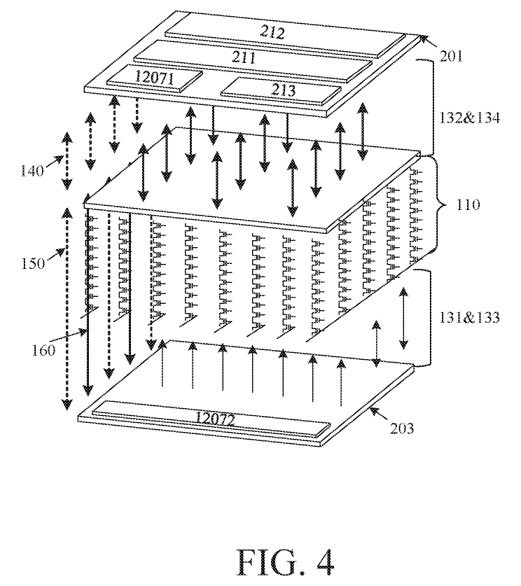

Based on this, in some examples, as shown in FIGS. 2 and 4, the control circuit 211, the analog-to-digital conversion circuit 212, and the data processing circuit 213 of the processing circuit 210, and the first input/output circuit 12071 of the peripheral circuit 120 may be disposed on the first semiconductor structure 201. The memory cell array 110 in the semiconductor device 100 is formed on the second semiconductor structure 202, and at least part of the peripheral circuit 120 (e.g., the second input/output circuit 12072) is formed on the third semiconductor structure 203.

The positions of the circuit structures in the computing in memory apparatus 200 are not specifically limited in the above examples of the present disclosure, and may be adjusted according to actual requirements.

In some examples, as shown in FIG. 4, the semiconductor device 100 further includes a first bonding layer 131, a second bonding layer 132, a third bonding layer 133, and a fourth bonding layer 134, and a first connection structure 140 penetrating through the memory cell array 110 and connected to the bit line BL and the second bonding layer 132. For example, the first connection structure 140 is a through-array contact (TAC). The memory cell array 110 is connected to the analog-to-digital conversion circuit 212 on the first semiconductor structure 201 through the bit line, the first connection structure 140, the second bonding layer 132 and the fourth bonding layer 134.

The semiconductor device 100 further includes a second connection structure 150 penetrating through the memory cell array 110. One end of the second connection structure 150 is connected to the second semiconductor structure 202, and the other end of the second connection structure 150 is connected to the first input/output circuit 12071 through the fourth bonding layer 134 and the second bonding layer 132.

The semiconductor device 100 further includes a third connection structure 160 penetrating through the memory cell array 110 and connected to a source layer (not shown) in the first semiconductor structure 201. For example, the third connection structure 160 is a through-array contact (TAC). At least part of the integrated circuits of the peripheral circuit 120 in the third semiconductor structure 203 are connected to the source layer through the third bonding layer 133, the first bonding layer 131, and the third connection structure 160.

It should be noted that in the example shown in FIG. 4 provided in the present disclosure, an interconnection structure is further included between each bonding layer and between each bonding layer and the memory cell array 110, to couple the memory cell array 110 to different circuits in the peripheral circuit 120.

Based on the above description, taking an example in which the computing in memory apparatus 200 is a solid-state electronic device (for example, the semiconductor device 100 is a NAND-type memory) that stores data information made by the semiconductor integrated circuit process for description of the following examples. Subsequent examples of the present disclosure do not limit the specific internal structure of the computing in memory apparatus 200.

In some examples, as shown in FIG. 5, the semiconductor device 100 may include a memory cell array 110 and circuit structures coupled to the memory cell array 110, such as a peripheral circuit 120.

As shown in FIG. 5, the memory cell array 110 may be a NAND flash memory cell array. For example, the memory cell array 110 is a circuit structure arranged in an array of NAND memory strings 1101. Each NAND memory string 1101 extends vertically on the substrate. For example, each NAND memory string 1101 may include a plurality of memory cells coupled in series and stacked vertically. Each of the memory cells is signaled in a state that keeps a continuous analog value (e.g., voltage or charge), and the analog value of the memory cell depends on the number of electrons captured within the memory cell region.

As an example, each memory cell in the memory cell array 110 may be a floating gate type of memory cell including a floating gate transistor, or a charge trapping type of memory cell including a charge trapping transistor. This is not limited in the present disclosure.

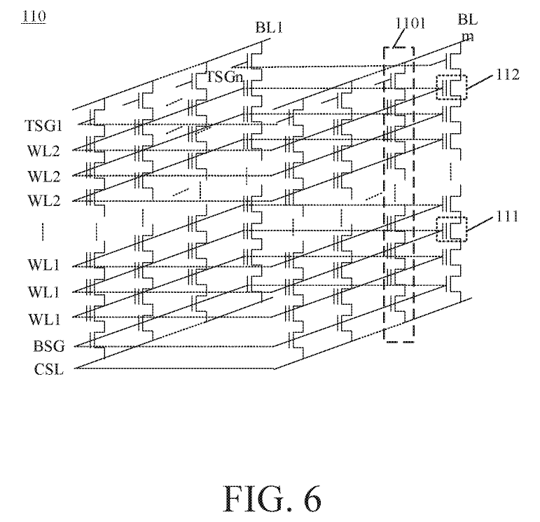

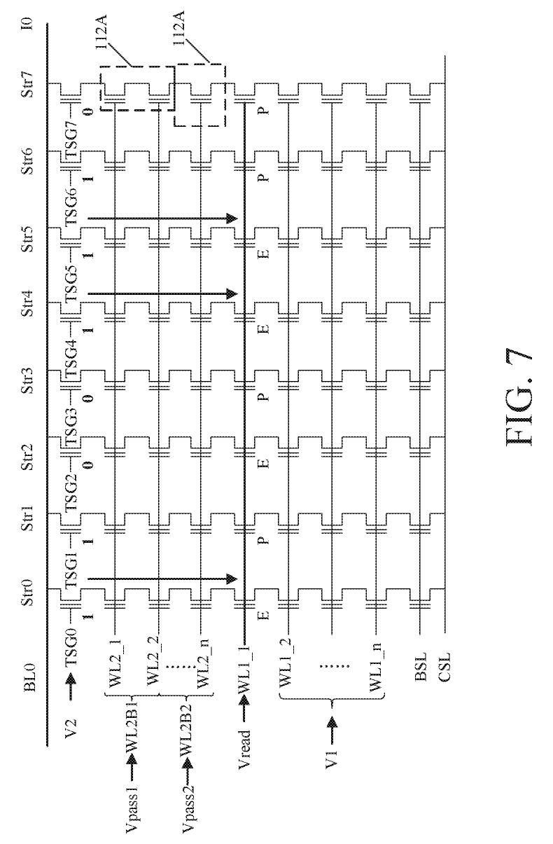

As shown in FIGS. 6 and 7, based on the structure and connection relationship of the memory cell array 110 and the peripheral circuit 120, at least one memory string of the plurality of memory strings 1101 in the semiconductor device 100 includes a plurality of first memory cells 111 and a plurality of second memory cells 112 connected. For example, the first memory cell 111 is mainly configured to store data for subsequent computation. The second memory cell 112 is mainly configured to adjust the current of the memory string 1101 where the second memory cell 112 is located.

The peripheral circuit 120 is coupled to one first memory cell of the plurality of first memory cells 111 through the first word line WL1, and is coupled to one of the plurality of second memory cells 112 through the second word line WL2. The word lines coupled to the plurality of second memory cells 112 include a first portion WL2B1 and a second portion WL2B1.

The peripheral circuit 120 is configured to apply a first read voltage Vread1 to a word line (for example, WL1) coupled to one first memory cell of the plurality of first memory cells 111 of the memory string 1101, apply a first pass voltage Vpass1 to the first portion of word lines WL2B1, and apply a second pass voltage Vpass2 to the second portion of word lines WL2B2 after performing a program operation on the plurality of first memory cells 111, where the second pass voltage Vpass2 is different from the first pass voltage Vpass1.

For example, the plurality of second memory cells 112 are divided into N memory cell groups 112A, and N is a positive integer greater than 1. For example, N is 2, 3, 4 .... For example, as shown in FIG. 7, N is 2, and word lines coupled to the plurality of second memory cells 112 includes a first portion WL2B1 and a second portion WL2B2. The plurality of second memory cells 112 coupled to the first portion of word lines WL2B1 (e.g., word lines WL2_1 and WL2_2) is one memory cell group 112A, and the plurality of second memory cells 112 coupled to the second portion of word lines WL2B2 (e.g., word lines WL2_3 to WL2_n) is one memory cell group 112A.

A first pass voltage Vpass1 is applied to the first portion of word lines WL2B1, a second pass voltage Vpass2 is applied to the second portion of word lines WL2B2, and the second pass voltage Vpass2 is different from the first pass voltage Vpass1. A current on a signal line coupled to one end of the memory string 1101 is acquired.

It may be understood that the “first pass voltage” and the “second pass voltage” are used to distinguish different voltages applied on different portions of word lines, and do not limit the specific voltage value, and may be adjusted according to the memory state of the second memory cell 112. The “first read voltage” refers to the voltage applied to the word line (e.g., word line WL1_1 in FIG. 7) coupled to the first memory cell 111 in the phase of detecting whether the current passing through the memory string 1101 is within the target current range. The “second read voltage” mentioned in the subsequent example refers to the voltage applied to the word line coupled to the first memory cell 111 during an in-memory computation phase of the semiconductor device 100. It may be understood that the “first read voltage” and the “second read voltage” are used to distinguish voltages applied on the first memory cell 111 of the memory string 1101 in different phases, and do not limit whether the voltage values are the same, and may be set according to actual requirements.

In the above semiconductor device 100, the memory cell array 110 includes two types of memory cells for different functional purposes, for example, a memory cell (e.g., the first memory cell 111) coupled to the first word line WL1 is configured to store a weight and participate in an in-memory computation, and a memory cell (e.g., the second memory cell 112) coupled to the second word line WL2 is configured to adjust a current of the memory string 1101 where the memory cell is located. In some examples, based on the current of one memory string 1101 not being within the target current range or the current difference between the plurality of memory strings 1101 exceeding a certain range (that is, since the current on the sensing bit line is actually the sum of the currents of the plurality of memory strings, even if the current of one memory string satisfies the target current range, large current difference between the adjacent memory strings 1101 may affect the precision of the sensing current), different pass voltages can be applied to different portions of word lines coupled with the second memory cell 112. For example, a first pass voltage can be applied to the first portion of word lines, a second pass voltage is applied to the second portion of word lines (the first pass voltage is different from the second pass voltage). The current passing through the memory string 1101 may be adjusted, and may be adjusted multiple times until the current value of the memory string 1101 is in the target current range Ig. Dynamic adjustment is achieved through real-time detection, so that the stability of the pass current on the memory string 1101 is improved, and the purpose of improving the in-memory computation precision of the memory cell array 110 is achieved.

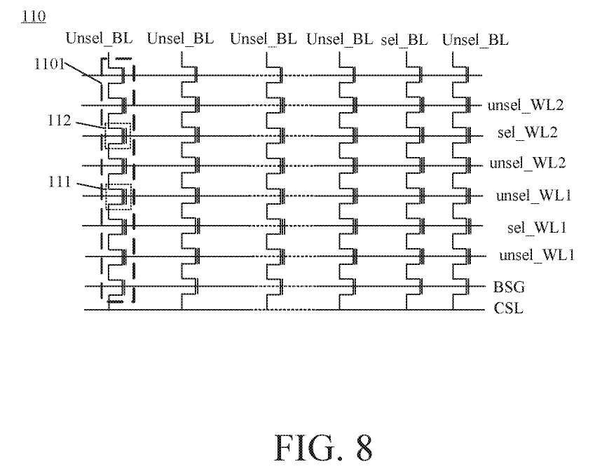

In some examples, as shown in FIG. 8, the plurality of first word lines WL1 coupled to the first memory cell 111 includes a selected word line sel_WL1 and an adjacent word line unsel_WL1 adjacent to the selected word line sel_WL1.

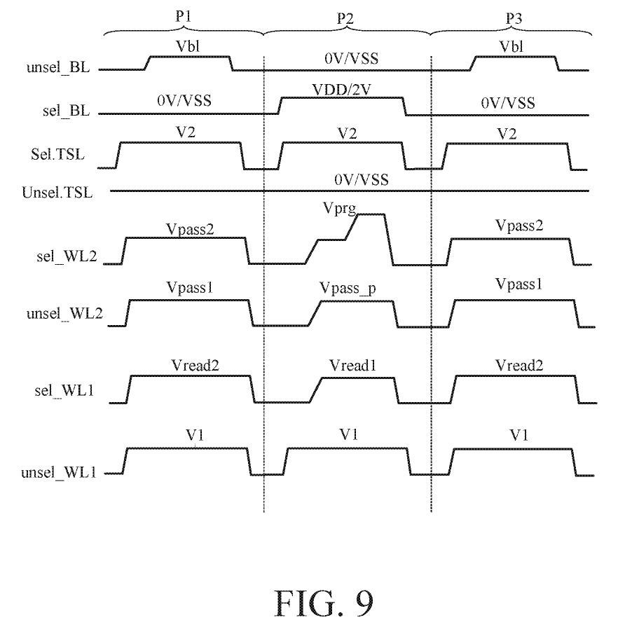

FIG. 9 shows a schematic diagram of a voltage waveform in the process of compensating the current passing through the memory string 1101, in a case where the memory string 1101 includes a plurality of memory cell groups 112A. The first phase P1 may represent a phase in which the current of the memory string 1101 is acquired, and the current of a portion of the memory string 1101 is not within the target current range Ig; the second phase P2 may represent a phase in which the threshold voltage level Vth of at least part of the second memory cell 112 on the memory string 1101 is programmed after determining that the current of the memory string 1101 is not within the target current range Ig in the first phase P1; and the third phase P3 may represent a phase in which a read operation is performed on the memory string 1101 to obtain the analog computing information after the current of the memory string 1101 is in the target current range Ig in the second phase P2.

It may be understood that the “target current range Ig” may refer to a current value range in an ideal state of one memory string 1101, or may be a current value range after eliminating the large difference between the currents of the adjacent memory strings 1101. For example, since the current on the sensing bit line BL is actually the sum of the currents of the plurality of memory strings 1101 (referring to FIGS. 6 and 7), even if the current of one of the memory strings 1101 satisfies the target current range for the one memory string 1101, the difference between the currents of the adjacent memory strings will also affect the accuracy of the sensing current. Therefore, the current value range of the target current range Ig may be different in different scenarios. This is not specifically limited in the examples provided in the present disclosure, as long as the specific value of the target current range Ig can reduce the read error and improve the memory computing accuracy of the memory cell.

As shown in FIG. 9, the peripheral circuit 120 is configured to, in the first phase P1, perform a first operation (e.g., an operation of acquiring the current of the memory string 1101) on the first memory cell 111 coupled to the selected word line sel_WL1, set the voltage applied to the adjacent word line unsel_WL1 to be the first turn-on voltage V1 and the voltage applied on the selected word line sel_WL1 to be the read voltage Vread (e.g., the second read voltage Vread2); and apply the second turn-on voltage V2 to the top select gate line TSL coupled to the memory string 1101, where different pass voltages Vpass are applied to the word lines coupled to different memory cell groups 112A (e.g., Vpass1 is applied to unsel_WL2, and Vpass2 is applied to sel_WL2).

For example, in the first phase P1, the peripheral circuit 120 may set the first turn-on voltage V1 applied to the adjacent word line unsel_WL1 and the second turn-on voltage V2 applied to the top select gate line TSL coupled to the memory string 1101 under the condition that the read voltage Vread (e.g., the second read voltage Vread2) of the stored data of the first memory cell 111 coupled to the selected word line sel_WL1 is acquired, and apply the first pass voltage Vpass 1 to the first portion of word lines WL2B1 (the word lines coupled to one of the memory cell groups 112A), and apply the second pass voltage Vpass 2 to the second portion of word lines WL2B2 (the word lines coupled to another one of the memory cell groups 112A), where the first pass voltage Vpass 1 is different from the second pass voltage Vpass 2. However, based on this, there is a case in which the acquired current of some memory strings 1101 is not within the target current range Ig, or the current difference between some adjacent memory strings 1101 is large and is not within the target current range Ig. For example, the current of the memory string 1101 may be directly acquired, and whether the current value of the memory string 1101 is within the target current range Ig may be determined. For another example, based on the voltages applied to different word lines in the first phase P1, after the in-memory read operation is performed, the current of the memory string 1101 is acquired, whether there is an error exists in the acquired data of the first memory cell 111 on the memory string 1101, and then whether the current value of the memory string 1101 is within the target current range Ig is determined.

In the second phase P2, for the memory string 1101 in which the current of the memory string 1101 is not within the target current range Ig, a programming voltage may be applied to the word line coupled to one second memory cell 112 on the memory string 1101, and a turn-on voltage is applied to other word lines coupled to the memory string 1101 to program the second memory cell 112. At least part of the second memory cells 112 on the memory string 1101 may be programmed multiple times, until the threshold voltage level Vth of the second memory cells 112 reaches the target threshold voltage level Vth_goal, and the current of the memory string 1101 is within the target current range Ig.

For example, in response to the current of the memory string 1101 not being within the target current range Ig, a program operation may be performed on at least part of the second memory cells on the memory string 1101 until the threshold voltage level Vth of the second memory cells 112 reaches the target threshold voltage level Vth_goal. In this way, the magnitude of the current of the memory string 1101 may be adjusted until the current of the memory string 1101 is within the target current range Ig.

As another example, a pass voltage applied to word lines coupled to different second memory cell groups 112A may also be changed. For example, a first sub-pass voltage Vpass11 is applied to the first portion of word lines WL2B1, and a second sub-pass voltage Vpass21 is applied to the second portion of word lines WL2B2, where the second sub-pass voltage Vpass21 is different from the second pass voltage Vpass2, and the first sub-pass voltage Vpass11 is different from the first pass voltage Vpass1. For example, Vpass2 is increased or Vpass1 and the like (not shown) are increased. In this way, the magnitude of the current of the memory string 1101 can also be adjusted until the current of the memory string 1101 is within the target current range Ig, and the number of times of programming the second memory cell 112 can be reduced by changing the first pass voltage Vpass1 or changing the second pass voltage Vpass2, which is beneficial for reducing the time for adjusting the current of the memory string 1101 to be the target current range Ig, and thus reducing the operation complexity.

The above two manners may be implemented separately or jointly to adjust the current of the memory string 1101, so as to improve the flexibility and precision of regulation and control of the current of the memory string 1101, and facilitate improving the precision of the in-memory computation of the semiconductor device 100.

In some examples, as shown in FIG. 9, the peripheral circuit 120 is configured to, in a third phase P3 after the second phase P2, apply a second read voltage Vread2 to a word line (e.g. sel_WL1) coupled to one first memory cell of the plurality of first memory cells 111 of the memory string 1101, apply a first pass voltage V1 to the word lines coupled to the remaining first memory cells 111, and apply a second pass voltage V2 to the top select gate line TSL coupled to the memory string 1101 in response to the current on the memory string 1101 being within the target current range Ig; and apply a first pass voltage Vpass 1 to the first portion of word lines WL2B1 and a second pass voltage Vpass 2 to the second portion of word lines WL2B2, where the first pass voltage Vpass 1 is different from the second pass voltage Vpass 2. A current on a signal line (for example, a common source line CSL or a bit line BL) coupled to one end of the memory string 1101 is acquired to obtain analog computing information.

For example, after adjusting the current of the memory string 1101 to be within the target current range Ig in the second phase P2, in the third phase P3, the pass voltage in the case of being in the target current range Ig applied to the second portion of word lines WL2B2 may be kept by keeping the pass voltage in the case of being in the target current range Ig applied to the first portion of word lines WL2B1 for the word line (e.g., sel_WL1) coupled to the target first memory cell 111. For example, a first pass voltage Vpass1 is applied to a first portion of word lines WL2B1 (word lines coupled to one of the memory cell groups 112A), and a second pass voltage Vpass2 is applied to a second portion of word lines WL2B2 (word lines coupled to one of the memory cell groups 112A), where the first pass voltage Vpass1 is different from the second pass voltage Vpass2; and data stored on a first memory cell 111 of the memory string 1101 is acquired. In this way, the error of the current of the memory string 1101 or the current difference between the adjacent memory strings 1101 can be reduced or avoided, the stability of the current passing on the memory string 1101 can be improved, and the accuracy of acquiring the current on the signal line (for example, the common source line CSL or the bit line BL) coupled to one end of the memory string 1101 can be improved.

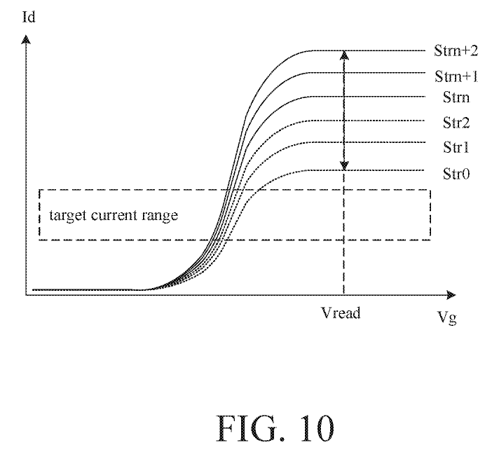

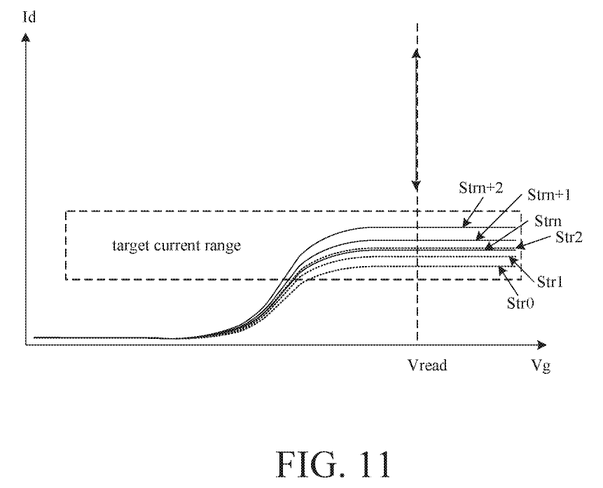

It should be noted that, FIG. 10 shows the current variation of the adjacent memory string 1101 in the case that the initial threshold voltage level Vth of the second memory cell 112 in the adjacent plurality of memory strings 1101 (Str0, Str1, Str2,..., Strn, Strn+1, and Strn+2), or the number or proportion of the second memory cells 112 in the initial program state and the erase state, and the passing voltage is initially applied to the word line (for example, the word line WL2) coupled to the second memory cell 112. FIG. 11 shows the current variation of the adjacent memory strings 1101 in the case of at least one operation of performing a program operation on at least part of the second memory cells 112 of the adjacent plurality of memory strings 1101 (Str0, Str1, Str2,..., Strn, Strn+1, and Strn+2) or adjusting the number or proportion of the programmed second memory cells 112, and resetting the pass voltage Vpass applied to the word lines coupled to the different memory cell groups 112A. In this way, the current difference between adjacent memory strings 1101 can be reduced, and the in-memory computation precision of the memory strings 1101 of the memory cell array 110 can be improved. The following examples illustrate the structure and method for implementing the effects shown in FIG. 11.

The above example of three phases (P1, P2, and P3) of compensating the current passing through the memory string 1101 as shown in FIG. 9 is a process for sensing that the current on the memory string 1101 is in the target current range Ig and performing the analog computation after detecting whether the current on the memory string 1101 is within the target current range Ig, and after programming at least part of the second memory cells 112 on the memory string 1101. In fact, there is a case of sensing that the current on the memory string 1101 is still not within the target current range Ig after programming at least part of the second memory cells 112 on the memory string 1101. In this case, at least part of the second memory cells 112 on the memory string 1101 may be programmed again, or the first pass voltage Vpass1 applied to the first portion of the word lines WL2B1 and the second pass voltage Vpass2 applied to the second portion of the word lines WL2B2 may be set, until the current on the memory string 1101 is within the target current range Ig, and then analog computation is performed on the first memory cell 111 of the memory string 1101. That is, the sequence of the operations of programming the second memory cell 112, adjusting the first pass voltage Vpass1 applied to the first portion of word lines WL2B1 and the second pass voltage Vpass2 applied to the second portion of word lines WL2B2 may be adjusted according to actual requirements, as long as the current on the memory string 1101 is within the target current range Ig.

For example, the peripheral circuit 120 is configured to apply a first pass voltage Vpass1 to the first portion of word lines WLB1, apply a second pass voltage Vpass2 to the second portion of word lines WLB2 after performing a program operation on at least part of the second memory cells 112 on the memory string 1101, where the current of the memory string 1101 is within the target current range Ig.

Alternatively, after applying the first pass voltage Vpass1 to the first portion of word lines WLB1, and applying the second pass voltage Vpass2 to the second portion of word lines WLB2, program operation is performed on at least part of the second memory cell 112 on the memory string 1101, and the threshold voltage level Vth of the second memory cell 112 reaches the target threshold voltage level Vth_goal; the target threshold voltage level Vth_goal represents the program state of the second memory cell 112 satisfying the target current range Ig.

In this way, by the operation of continuously programming the at least part of the second memory cells 112 in the memory string 1101 for multiple times, or the operation of continuously changing the first pass voltage Vpass1 applied to the first portion of the word lines WL2B1 and the second pass voltage Vpass2 applied to the second portion of the word lines WL2B2 for multiple times, or these two different operations, it is beneficial to select different operations according to the precision of the current of the memory string 1101. Consequently, the step of compensating the current of the memory string 1101 is simplified, the accuracy of adjusting the current of the memory string 1101 is improved, and the stability of the current passing through the memory string 1101 is improved.

The following explains that the current passing on the memory string 1101 is within the target current range Ig to reduce the difference between the currents of the adjacent memory strings 1101 from the perspective that how to set the pass voltage Vpass applied on the word lines coupled to different memory cell groups 112A.

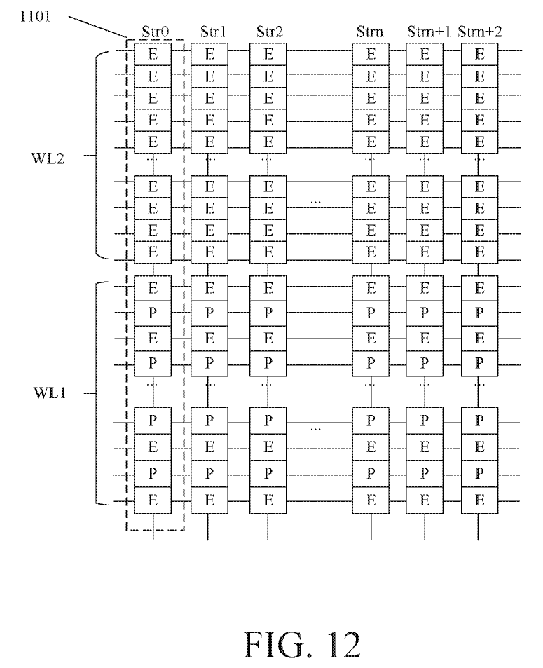

In some examples, as shown in FIGS. 12-14, the plurality of second memory cells 112 of the plurality of memory strings 1101 are configured to have a program state and an erase state.

A ratio of a number of second memory cells 112 in the erase state E to a number of second memory cells 112 in the program state P in the first portion of word lines WL2B1 is a first ratio Q1.

A ratio of the number of the second memory cells 112 in the erase state E to the number of the second memory cells 112 in the program state P in the second portion of word lines WL2B2 is a second ratio Q2.

The first ratio Q1 is greater than the second ratio Q2, and the first pass voltage Vpass1 is less than the second pass voltage Vpass2.

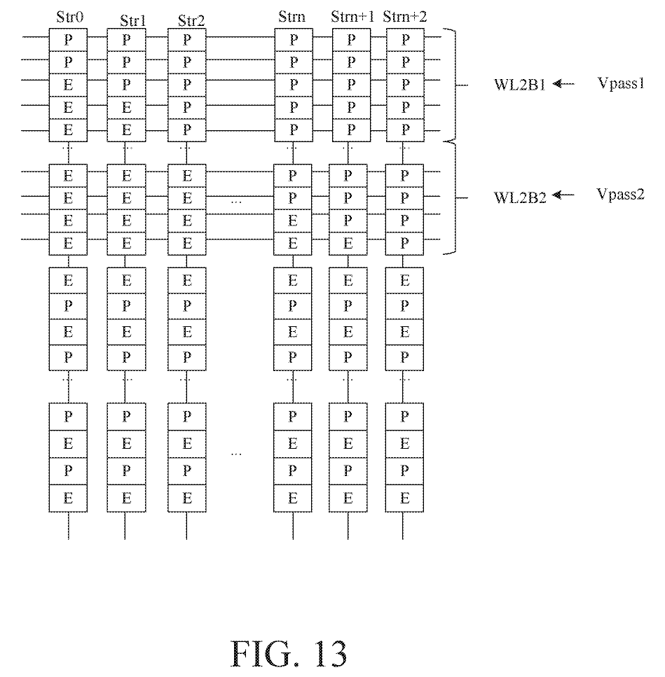

For example, as shown in FIG. 13, one memory string 1101 includes 2 memory cell groups 112A, where the plurality of second memory cells 112 coupled to the first portion of word lines WL2B1 (e.g., word lines WL2_1 and WL2_2) is one memory cell group 112A, and the second plurality of memory cells 112 coupled to the second portion of word lines WL2B2 (e.g., word lines WL2_3 to WL2_n) is one memory cell group 112A.

A ratio of the number of the second memory cells 112 in the erase state E to the number of the second memory cells 112 in the program state P in the second memory cells 112 coupled to the first portion of word lines WL2B1 (namely one memory cell group 112A) is the first ratio Q1.

A ratio of the number of the second memory cells 112 in the erase state E to the number of the second memory cells 112 in the program state P in the second memory cells 112 coupled to the second portion of word lines WL2B2 (namely one memory cell group 112A) is the second ratio Q2.

For example, the first ratio Q1 is 1/5, and the second ratio Q2 is 1/6. The first ratio Q1 is greater than the second ratio Q2, and the first pass voltage Vpass1 is less than the second pass voltage Vpass2. It may be understood that the higher the proportion of the second memory cells 112 in the erase state is, the smaller the amount of charge required for this portion of the word lines is. Since the memory states of the second memory cells coupled to different portions of word lines are different, the pass voltages applied to different portions of word lines are different. So the current difference between different memory strings 1101 can be reduced, and the stability of the pass current on the memory string 1101 is improved.

In some examples, the word lines coupled to the plurality of second memory cells 112 further include a third portion WL2B3 to an N-th portion WL2Bn, where N is a positive integer greater than or equal to 3. For example, the word lines coupled to the plurality of second memory cells 112 include a first portion of word lines WL2B1, a second portion of word lines WL2B2, a third portion of word lines WL2B3,..., an N-th portion of word lines WL2Bn.

The peripheral circuit 120 is configured to apply different pass voltages Vpass to different portions of word lines WL2B.

As an example, by dividing into the plurality of portions of word lines WL2B, different pass voltages Vpass can be applied through different portions of word lines WL2B, the current passing through one memory string 1101 can be adjusted, the precision of adjusting the current can be improved, the current difference between different memory strings 1101 can be reduced, and the stability of pass current on the memory string 1101 can be improved.

In some examples, the portion of word lines WL2B with a larger ratio Q of the number of the second memory cells 112 in the erase state E to the number of the second memory cells 112 in the program state P in the plurality of portions of word lines WL2B are applied to a smaller pass voltage.

For example, the ratios Q of the number of the second memory cells 112 in the erase state E to the number of the second memory cells 112 in the program state P in the plurality of portions of word lines WL2B are different, and the portion of word lines WL2B with a larger ratio Q are applied to a smaller pass voltage Vpass.

In some examples, ratios Q of the number of the second memory cells 112 in the erase state E to the number of the second memory cells 112 in the program state P in the second memory cells 112 coupled to different portions of word lines WL2B are different.

In this way, based on the memory cell groups 112A of different ratios Q, by respectively setting the plurality of portions of word lines WL2B, the accuracy of adjusting the current magnitude can be further improved, the current difference between different memory strings 1101 is reduced, and the stability of the pass current on the memory string 1101 is improved.

In some examples, the peripheral circuit 120 is configured to perform a program operation on at least part of the second memory cells 112 in an erase state E on a memory string in response to a current on the memory string 1101 not being within the target current range Ig.

For example, as shown in FIGS. 9 and 12 to 14 the initial threshold voltage levels Vth of the plurality of second memory cells 112 in one memory string 1101 may all be in an erase state E (refer to FIG. 12). The peripheral circuit 120 is configured to perform a first program operation on at least part of the second memory cells 112 in the erase state E on the memory string 1101 in response to the current value of the memory string 1101 being not within the target current range Ig in the second phase P2.

After performing the first program operation, the current of the memory string 1101 is acquired and it is determined whether the current is within the target current range Ig. Based on the current value of the memory string 1101 not being within the target current range Ig, a second program operation may be performed on at least one of the second memory cells until the threshold voltage level Vth of the second memory cells 112 reaches the target threshold voltage level Vth_goal. The target threshold voltage level Vth_goal represents the program state of the second memory cells 112 that satisfies the target current range Ig.

In this way, by performing the second program operation after the first program operation, the threshold voltage level Vth of the second memory cell 112 in one memory string 1101 may be reset, or the portion of the second memory cells 112 on which the program operation is not performed may be programmed to increase the number of the second memory cells 112 in the program state. By detecting the current of the memory string 1101 in real time, the current of the memory string 1101 can be adjusted to be within the target current range Ig through multiple program operations, thereby improving the accuracy of subsequent computation.

It should be noted that the “first program operation” is named based on the existence of the “second program operation,” and if only one program operation is needed to make the current of the memory string 1101 in the target current range Ig, only the “first program operation” is performed. As such, the different naming of the “first program operation” and the “second program operation” can reflect the number of times of performing the program operation on the second memory cells 112 in the memory string 1101, and does not limit whether the object of the program operation is the second memory cell 112 on which the program operation has been performed.

The “target threshold voltage level Vth_goal” is a threshold voltage level Vth of the second memory cell 112 in a case where the valid data in the first memory cell 111 can be obtained based on a driving condition (for example, the voltage applied on the word line WL and the bit line BL), and the current value of the memory string 1101 to which the first memory cell 111 belongs is within the target current range Ig to improve the accuracy of reading data. The “target threshold voltage level Vth_goal” may be adjusted according to the actual operating state and the application scenario of the semiconductor device 100, and is not necessarily a fixed value. The example provided in the present disclosure does not restrict the specific value of the “target threshold voltage level Vth_goal.”

The program operation described above may program the threshold voltage level Vth of the second memory cell 112 to the target threshold voltage level Vth_goal by setting the voltage applied on the word line (e.g., WL2) and/or the bit line BL coupled to the second memory cell 112 of the memory string 1101.

It should be noted that, according to different memory types of the second memory cells 112, the threshold voltage levels Vth of different program states P are different. For example, the memory type of the memory cell includes any one of a single level cell (SLC), a multi-level cell (MLC), a triple level cell (TLC), and a quad level cell (QLC). For example, in a case where the memory type of the second memory cell 112 includes SLC, the threshold voltage level Vth of the second memory cell 112 in the program state P is the same. For another example, in a case where the memory type of the second memory cell 112 includes a multi-level memory type such as MLC and TLC, the threshold voltage levels of the program states P of different second memory cells 112 in one memory string 1101 may be the same or different. The examples provided in the present disclosure are not limited, and may be set according to actual situation.

For example, the memory type of the second memory cell 112 includes an MLC type. Each memory cell of the MLC has four possible memory states of a first memory state, a second memory state, a third memory state, and a fourth memory state. The first memory state (e.g., “00”) corresponds to a first threshold voltage range, the second memory state (e.g., “01”) corresponds to a second threshold voltage range, the third memory state (e.g., “10”) corresponds to a third threshold voltage range, and the fourth memory state (e.g., “11”) corresponds to a fourth threshold voltage range. As such, the fourth memory state (e.g., “11”) is used as the erase state E, the first memory state (e.g., “00”), the second memory state (e.g., “01”), and the third memory state (e.g., “10”) are used as the program state P. The threshold voltage levels Vth of the three program states P of the first memory state (e.g., “00”), the second memory state (e.g., “01”), and the third memory state (e.g., “10”) are different. Similarly, the memory types of the second memory cells 112 include multi-level memory types such as TLC and QLC. The threshold voltage levels of the second memory cells 112 in different program states P are different, and the resistance values of the equivalent resistances of the second memory cells 112 represented by the second memory cells 112 in different program states P are different.

In some examples, the program state P of the second memory cell 112 includes a plurality of threshold voltage levels Vth in successive different threshold voltage ranges. It can be understood that different threshold voltage levels Vth represent different resistance values of the equivalent resistors of the second memory cells 112.

The peripheral circuit 120 is configured to program threshold voltage levels Vth of the different second memory cells 112 on the memory string 1101 to be different.

For example, the memory type of the second memory cell 112 includes an MLC type. The second memory cell 112 includes the fourth memory state (e.g., “11”) as the erase state E, and includes the first memory state (e.g., “00”), the second memory state (e.g., “01”), and the third memory state (e.g., “10”) as the program state P.

For example, in the second phase P2, based on the current value of the single memory string 1101 not being within the target current range Ig, the program states P of the different second memory cells 112 on the memory string 1101 are respectively programmed to be different threshold voltage levels Vth. As such, in the case that the pass voltage subsequently applied to the word line coupled to the second memory cell 112 does not change, the threshold voltage level Vth of the second memory cell 112 can be individually programmed in this phase to adjust the current magnitude of the memory string 1101.

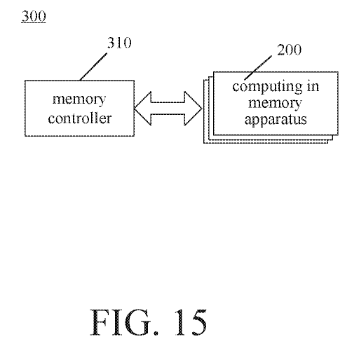

In some examples, as shown in FIG. 15, an example of the present disclosure provides a memory system 300. The memory system 300 includes one or more computing in memory apparatuses 200 and a memory controller 310. The memory controller 310 is configured to control the one or more computing in memory apparatuses 200.

For example, the memory controller 310 is coupled to the computing in memory apparatus 200, and is configured to control the computing in memory apparatus 200 to perform a program operation, program at least one second memory cell 112 in the at least one memory string 1101, and control the computing in memory apparatus 200 to perform a read operation based on the adjusted current of the memory string 1101 being within the target current range Ig, to acquire an adjusted in-memory computation result of the memory string 1101.

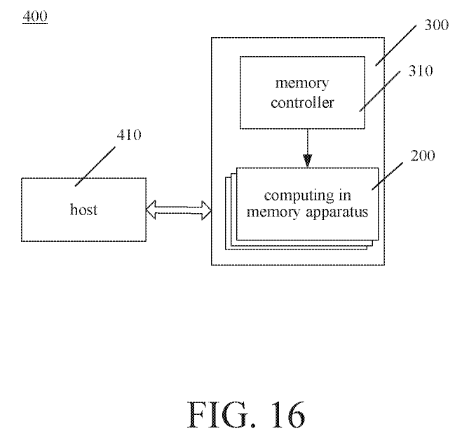

In some examples, as shown in FIG. 16, an example of the present disclosure provides an electronic device 400. For example, the electronic device 400 may include, but is not limited to, a mobile phone, a desktop computer, a laptop computer, a tablet computer, a vehicle computer, a game console, a printer, a pointing device, a wearable electronic device, a smart sensor, a virtual reality (VR) device, an augmented reality (AR) device, or any other suitable electronic device having a memory system 300 therein.

Referring to FIG. 16, the electronic device 400 may include a host 410 and a memory system 300.

The host 410 may be a processor (for example, a central processing unit (CPU), or a system on chip (SoC) (for example, an application processor (AP)) of the electronic device 400. The host 410 may be configured to send or receive data to or from the computing in memory apparatus 200.

The one or more computing in memory apparatuses 200 may be integrated in a same memory device. In this way, it is beneficial to apply the computing in memory apparatus 200 to different types of terminal electronic products.

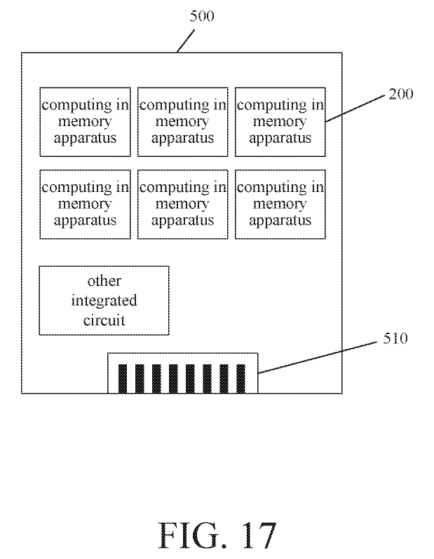

For example, as shown in FIG. 17, the present disclosure provides a readable storage medium 500. The readable storage medium 500 includes a stored computer program or instruction, and the computer program or the instruction, when executed, controls the device where the computer readable storage medium is located to implement the control method of the semiconductor device 100 provided in any one of the following examples.

For example, the type of the readable storage medium 500 includes other types of memory devices such as universal flash storage (UFS) or embedded multimedia card (eMMC) and the like.

There are many ways to integrate the integrated circuit of the memory device, for example, a single computing in memory apparatus 200 and related circuits may be integrated into one memory card, or a plurality of computing in memory apparatus 200 may be integrated together to form an SSD. It will be appreciated that the storage capacity and/or operating speed of the SSD is greater than the storage capacity and/or operating speed of the memory card.

For example, with continued reference to FIG. 17, the readable storage medium 500 further includes a connector 510. The connector 510 is configured to couple the readable storage medium 500 with a host (e.g., the host 410 in FIG. 16). For example, the connector 510 includes gold fingers.

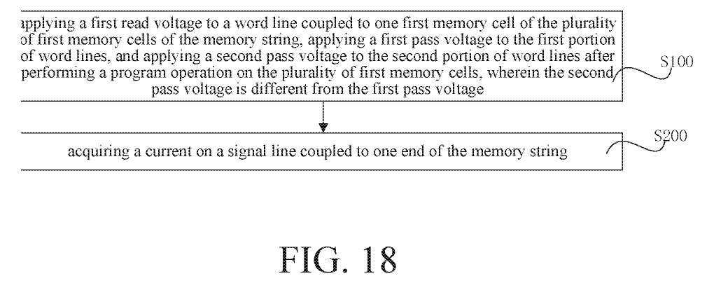

In some examples, as shown in FIGS. 18 to 22, the present disclosure further provides a control method of the semiconductor device 100.

For example, as shown in FIG. 7, the semiconductor device 100 includes a memory cell array including a plurality of memory strings 1101, where one memory string of the plurality of memory strings 1101 includes a plurality of first memory cells 111 and a plurality of second memory cells 112 connected. One first word line WL1 is coupled to one first memory cell of the plurality of first memory cells 111, and one second word line WL2 is coupled to one of the plurality of second memory cells 112.

The word lines coupled to the plurality of second memory cells 112 include a first portion WL2B1 and a second portion WL2B2.

As shown in FIG. 17, the method includes operations S100 to S300.

At S100, the method may include applying a first read voltage Vread1 to a word line (for example, WL1) coupled to one first memory cell of the plurality of first memory cells 111 of the memory string 1101, applying a first pass voltage Vpass1 to the first portion of word lines WL2B1, and applying a second pass voltage Vpass2 to the second portion of word lines WL2B2 after performing a program operation on the plurality of first memory cells 111, where the second pass voltage Vpass2 is different from the first pass voltage Vpass1.

For example, the plurality of first memory cells 111 are programmed to store data.

A plurality of second memory cells 112 on one memory string 1101 are divided into N memory cell groups 112A, where N is 2, 3, 4, etc. For example, as shown in FIG. 13, one memory string 1101 includes 2 memory cell groups 112A, and different pass voltages (e.g., Vpass1, Vpass2) are applied to word lines coupled to different memory cell groups 112A.

At S200, the method may include acquiring a current on a signal line coupled to one end of the memory string 1101.

For example, the current on the bit line BL or the common source line CSL coupled to one end of the memory string 1101 is acquired, and whether the current on the memory string 1101 is within the target current range Ig is determined.

In the above semiconductor device 100, the memory cell array 110 includes two types of memory cells for different functional purposes, for example, a memory cell (e.g., the first memory cell 111) coupled to the first word line WL1 is configured to store a weight and participate in an in-memory computation, and a memory cell (e.g., the second memory cell 112) coupled to the second word line WL2 is configured to adjust a current of the memory string 1101 where the memory cell is located. In some examples, based on the current of one memory string 1101 not being within the target current range or the current difference between the plurality of memory strings 1101 exceeding a certain range (that is, since the current on the sensing bit line is actually the sum of the currents of the plurality of memory strings, even if the current of one memory string satisfies the target current range, large current difference between the adjacent memory strings 1101 may affect the precision of the sensing current), different pass voltages can be applied to different portions of word lines coupled with the second memory cell 112. For example, a first pass voltage Vpass1 can be applied to the first portion of word lines, a second pass voltage Vpass2 is applied to the second portion of word lines, and the first pass voltage Vpass1 is different from the second pass voltage Vpass2. The current passing through the memory string 1101 may be adjusted, and may be adjusted multiple times until the current value of the memory string 1101 is in the target current range Ig. Dynamic adjustment can be achieved through real-time detection, so that the stability of the pass current on the memory string 1101 is improved, and the purpose of improving the in-memory computation precision of the memory cell array 110 is achieved.

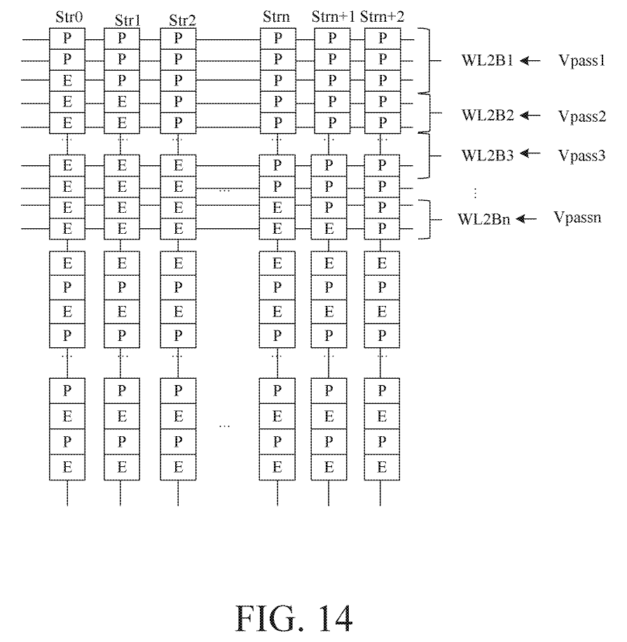

In some examples, as shown in FIGS. 13 and 14, the plurality of second memory cells 112 of the plurality of memory strings 1101 are configured to have a program state and an erase state.

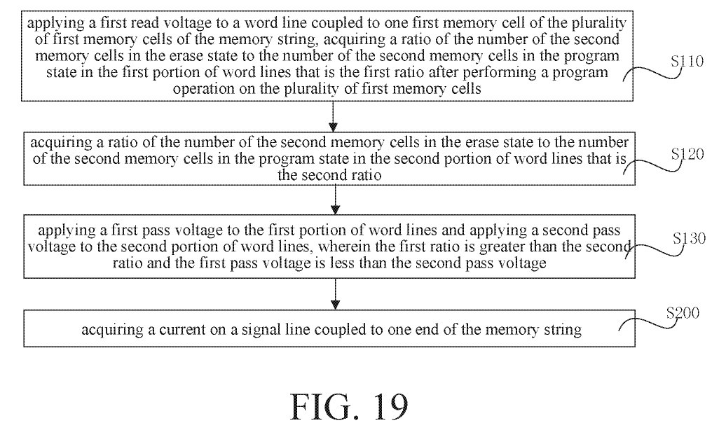

As shown in FIG. 19, the method includes operations S110, S120, and S130.

At S110, the method may include acquiring a ratio of the number of the second memory cells 112 in the erase state E to the number of the second memory cells 112 in the program state P in the second memory cells 112 coupled to the first portion of word lines WL2B1 that is the first ratio Q1.

At S120, the method may include acquiring a ratio of the number of the second memory cells 112 in the erase state E to the number of the second memory cells 112 in the program state P in the second memory cells 112 coupled to the second portion of word lines WL2B2 that is the second ratio Q2.

At S130, the method may include applying a first pass voltage Vpass1 to the first portion of word lines WL2B1, and applying a second pass voltage Vpass2 to the second portion of word lines WL2B2.

The first ratio Q1 is greater than the second ratio Q2, and the first pass voltage Vpass1is less than the second pass voltage Vpass2.

For example, as shown in FIG. 13, one memory string 1101 includes 2 memory cell groups 112A, where the plurality of second memory cells 112 coupled to the first portion of word lines WL2B1 (e.g., word lines WL2_1 and WL2_2) is one memory cell group 112A, and the second plurality of memory cells 112 coupled to the second portion of word lines WL2B2 (e.g., word lines WL2_3 to WL2_n) is one memory cell group 112A.

A ratio of the number of the second memory cells 112 in the erase state E to the number of the second memory cells 112 in the program state P in the second memory cells 112 coupled to the first portion of word lines WL2B1 (namely one memory cell group 112A) is the first ratio Q1.

A ratio of the number of the second memory cells 112 in the erase state E to the number of the second memory cells 112 in the program state P in the second memory cells 112 coupled to the second portion of word lines WL2B2 (namely one memory cell group 112A) is the second ratio Q2.

For example, the first ratio Q1 is 1/5, and the second ratio Q2 is 1/6. The first ratio Q1 is greater than the second ratio Q2, and the first pass voltage Vpass1 is less than the second pass voltage Vpass2. It may be understood that the higher the proportion of the second memory cells 112 in the erase state is, the smaller the amount of charge required for this portion of the word lines is. Since the memory states of the second memory cells coupled to different portions of word lines are different, the pass voltages applied to different portions of word lines are different. So the current difference between different memory strings 1101 can be reduced, and the stability of the pass current on the memory string 1101 is improved.

In some examples, as shown in FIG. 14, the word lines (for example, WL2) coupled to the plurality of second memory cells 112 further include a third portion WL2B3 to an N-th portion WL2Bn, where N is a positive integer greater than or equal to 3. For example, the word lines coupled to the plurality of second memory cells 112 include a first portion of word lines WL2B1, a second portion of word lines WL2B2, a third portion of word lines WL2B3,..., an N-th portion of word lines WL2Bn.

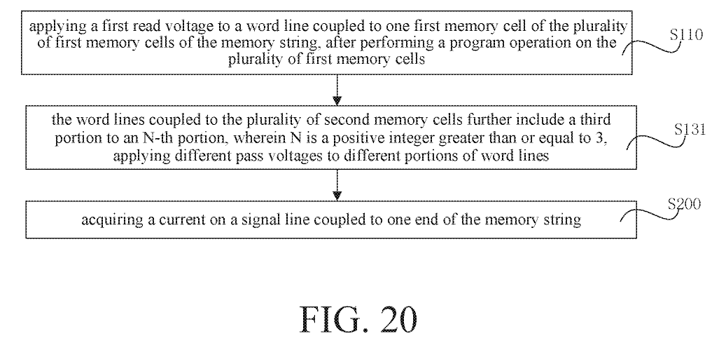

As shown in FIG. 20, the method includes operation S131.

At S131, the method may include applying different pass voltages to different portions of word lines.

As an example, by dividing into the plurality of portions of word lines WL2B, different pass voltages Vpass can be applied to different portions of word lines WL2B, the current passing through one memory string 1101 can be adjusted, the precision of adjusting the current can be improved, the current difference between different memory strings 1101 can be reduced, and the stability of pass current on the memory string 1101 can be improved.

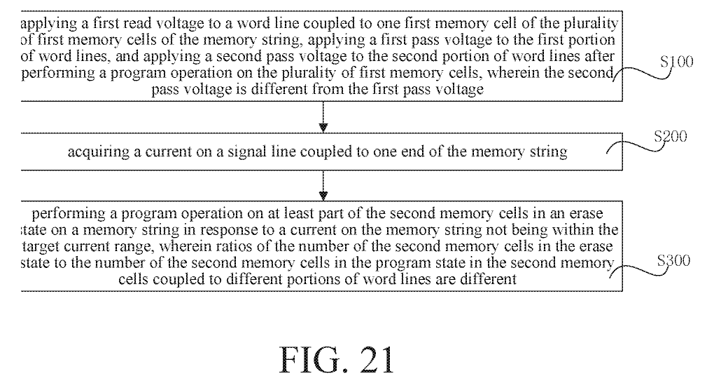

In some examples, as shown in FIG. 21, the control method includes S300.

At S300, the method may include performing a program operation on at least part of the second memory cells 112 in an erase state E on a memory string in response to a current on the memory string 1101 not being within the target current range Ig. Ratios Q of the number of the second memory cells 112 in the erase state E to the number of the second memory cells 112 in the program state P in the second memory cells 112 coupled to different portions of word lines are different.

For example, as shown in FIGS. 9 and 12 to 14, the initial threshold voltage levels Vth of the plurality of second memory cells 112 in one memory string 1101 may all be in an erase state E (refer to FIG. 13). The peripheral circuit 120 is configured to perform a first program operation on at least part of the second memory cells 112 in the erase state E on the memory string 1101 based on the current value of the memory string 1101 being not within the target current range Ig in the second phase P2.

After performing the first program operation, the current of the memory string 1101 is acquired and it is determined whether the current is within the target current range Ig. Based on the current value of the memory string 1101 not being within the target current range Ig, a second program operation may be performed on at least one of the second memory cells until the threshold voltage level Vth of the second memory cells 112 reaches the target threshold voltage level Vth_goal. The target threshold voltage level Vth_goal represents the program state of the second memory cells 112 that satisfies the target current range Ig.

In this way, by performing the second program operation after the first program operation, the threshold voltage level Vth of the second memory cell 112 in one memory string 1101 may be reset, or the portion of the second memory cells 112 on which the program operation is not performed may be programmed to increase the number of the second memory cells 112 in the program state. For example, in the second memory cell 112 coupled to different portions of word lines, the ratios Q of the number of the second memory cells 112 in the erase state E to the number of the second memory cells 112 in the program state P are different. By detecting the current of the memory string 1101 in real time, the memory state of the second memory cell 112 in the memory string 1101 can be changed or the ratio of the erasing state E to the program state P of the second memory cells 112 coupled with different portions of word lines can be set by a plurality of program operations, so as to adjust the current of the memory string 1101 to be in the target current range Ig, thereby improving the accuracy of subsequent computation.

It should be noted that, the “first program operation” is named based on the existence of the “second program operation,” and if only one program operation is needed to make the current of the memory string 1101 in the target current range Ig, only the “first program operation” is performed. As such, the different naming of the “first program operation” and the “second program operation” can reflect the number of times of performing the program operation on the second memory cells 112 in the memory string 1101, and does not limit whether the object of the program operation is the second memory cell 112 on which the program operation has performed.

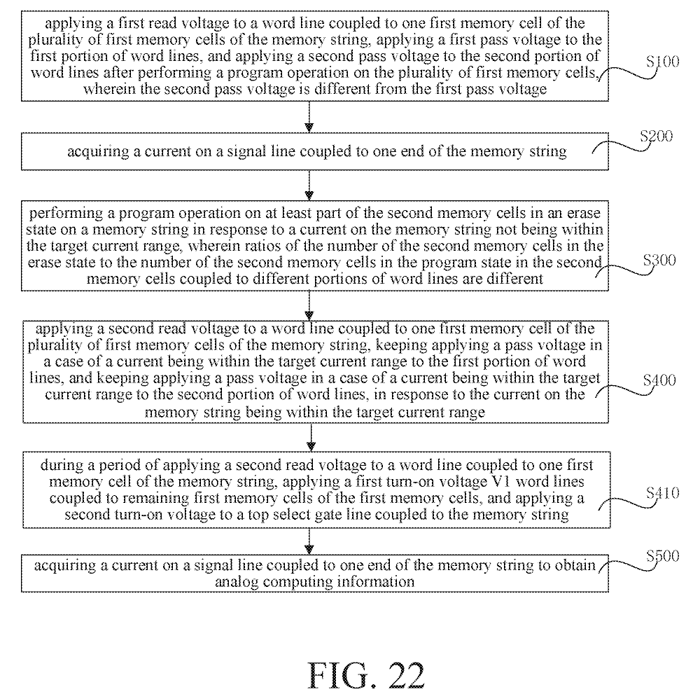

In some examples, as shown in FIG. 22, the method includes operations S400 and S500.

At S400, the method may include applying a second read voltage Vread2 to a word line (for example, sel_WL1) coupled to one first memory cell of the plurality of first memory cells 111 of the memory string 1101, keeping applying a pass voltage in a case of being within the target current range Ig to the first portion of word lines WL2B1, and keeping applying a pass voltage in a case of being within the target current range Ig to the second portion of word lines WL2B1, in response to the current on the memory string 1101 being within the target current range Ig.

For example, based on the current on the memory string 1101 being within the target current range Ig, a plurality of pass voltages (e.g., Vpass1, Vpass2,...) applied to the word lines coupled to different memory cell groups 112A are kept, and then a second read voltage Vread2 is applied to a word line (e.g. sel_WL1) coupled to one first memory cell 111 in the memory string 1101.

As an example, as shown in FIG. 22, operation S400 includes operation S410.

At S410, the method may include, during a same period of applying a second read voltage Vread2 to a word line coupled to one first memory cell 111 of the memory string 1101, applying a first turn-on voltage V1 to word lines coupled to remaining first memory cells of the first memory cells, and applying a second turn-on voltage V2 to a top select gate line TSL coupled to the memory string 1101, to acquire a current on a signal line coupled to one end of the memory string 1101.

For example, during the same period of applying the second read voltage Vread2 to the word line (e.g., sel_WL1) coupled to one first memory cell 111 in the memory string 1101, setting the first turn-on voltage V1 applied to the adjacent word line unsel_WL1, and the second turn-on voltage V2 applied to the top select gate line TSL coupled to the memory string 1101, and the pass voltages Vpass1 and Vpass2 applied to the word lines coupled to two of the memory cell groups 112A.

At S500, the method may include acquiring a current on a signal line coupled to one end of the memory string 1101 to obtain analog computing information.

For example, a current on a signal line (for example, a common source line CSL or a bit line BL) coupled to one end of the memory string 1101 is acquired, and a computation result is obtained through an analog-to-digital converter and an NPU.

The foregoing is only an example of the present disclosure, but the protection scope of the present disclosure is not limited thereto, and any changes or replacements that can be easily conceived by those skilled in the art within the technical scope disclosed in the present disclosure should be covered within the protection scope of the present disclosure. Therefore, the protection scope of the present disclosure should be subject to the protection scope of the claims.

What is claimed is:

1. A semiconductor device, comprising:
a memory cell array including a plurality of memory strings, wherein one memory string of the plurality of memory strings includes a plurality of first memory cells and a plurality of second memory cells coupled, and word lines coupled to the plurality of second memory cells include a first portion of word lines and a second portion of word lines; and
a peripheral circuit configured to:
apply a first read voltage to a word line coupled to one first memory cell of the plurality of first memory cells, apply a first pass voltage to the first portion of word lines, and apply a second pass voltage to the second portion of word lines after performing a program operation on the plurality of first memory cells, wherein the second pass voltage is different from the first pass voltage; and
acquire a current on a signal line coupled to one end of the memory string, wherein the current on the memory string is within a target current range.

2. The semiconductor device of claim 1, wherein:
the plurality of second memory cells of the plurality of memory strings are configured to have a program state and an erase state,
in the first portion of word lines, a ratio of a number of the second memory cells in the erase state to a number of memory cells in the program state is a first ratio,
in the second portion of word lines, a ratio of the number of the second memory cells in the erase state to the number of the second memory cells in the program state is a second ratio, and
the first ratio is greater than the second ratio, and the first pass voltage is less than the second pass voltage.

3. The semiconductor device of claim 2, wherein:
the word lines coupled to the plurality of second memory cells further include a third portion to an N-th portion, wherein N is a positive integer greater than or equal to 3, and
the peripheral circuit is configured to apply different pass voltages to different portions of word lines.

4. The semiconductor device of claim 2, wherein in a plurality of portions of the word lines, a portion of word lines with a larger ratio of the number of the second memory cells in the erase state to the number of the second memory cells in the program state is applied with a smaller pass voltage.

5. The semiconductor device of claim 1, wherein, in different portions of word lines, ratios of a number of the second memory cells in an erase state to the number of the second memory cells in a program state are different.

6. The semiconductor device of claim 1, wherein the peripheral circuit is configured to:
perform a program operation on at least part of the second memory cells in an erase state on the memory string in response to the current on the memory string not being within the target current range.

7. The semiconductor device of claim 6, wherein:
a program state of the second memory cells includes a plurality of threshold voltage levels in successive different threshold voltage ranges, and
the peripheral circuit is configured to program threshold voltage levels of different second memory cells on the memory string to be different.

8. The semiconductor device of claim 6, wherein the peripheral circuit is configured to:
apply the first pass voltage to the first portion of word lines, and apply the second pass voltage to the second portion of word lines, wherein after performing a program operation on at least part of the second memory cells on the memory string, the current on the memory string is within the target current range; or
perform a program operation on at least part of the second memory cells on the memory string, after applying the first pass voltage to the first portion of word lines, and applying the second pass voltage to the second portion of word lines, wherein the current on the memory string is within the target current range.

9. The semiconductor device of claim 1, wherein the peripheral circuit is configured to:
apply a first sub-pass voltage to the first portion of word lines, and apply a second sub-pass voltage to the second portion of word lines in response to the current on the memory string not being within the target current range, wherein the second sub-pass voltage is different from the second pass voltage, and the first sub-pass voltage is different from the first pass voltage.

10. The semiconductor device of claim 1, wherein the peripheral circuit is configured to:
apply a second read voltage to a word line coupled to one first memory cell of the plurality of first memory cells of the memory string, apply a pass voltage in a case of a current being within the target current range to the first portion of word lines, and apply a pass voltage in a case of a current being within the target current range to the second portion of word lines, in response to the current on the memory string being within the target current range; and
acquire the current on the signal line coupled to the one end of the memory string to obtain analog computing information.

11. The semiconductor device of claim 10, wherein the peripheral circuit is configured to:
during a period of applying a second read voltage to a word line coupled to the one first memory cell of the first memory cells of the memory string, apply a first turn-on voltage to word lines coupled to remaining first memory cells of the first memory cells, and apply a second turn-on voltage to a top select gate line coupled to the memory string, to acquire the current on the signal line coupled to the one end of the memory string.

12. The semiconductor device of claim 1, wherein a signal line coupled to one end of the memory string includes a common source line or a bit line.

13. A memory apparatus, comprising:
one or more semiconductor devices, comprising:
a memory cell array including a plurality of memory strings, wherein one memory string of the plurality of memory strings includes a plurality of first memory cells and a plurality of second memory cells coupled, and word lines coupled to the plurality of second memory cells include a first portion of word lines and a second portion of word lines;
a peripheral circuit configured to:
apply a first read voltage to a word line coupled to one first memory cell of the plurality of first memory cells, apply a first pass voltage to the first portion of word lines, and apply a second pass voltage to the second portion of word lines after performing a program operation on the plurality of first memory cells, wherein the second pass voltage is different from the first pass voltage; and
acquire a current on a signal line coupled to one end of the memory string, wherein the current on the memory string is within a target current range,
wherein the semiconductor device is configured to perform a first operation on weight information and input data to obtain analog computing information; and
a processing circuit coupled to the semiconductor device, and configured to determine an operation result based on the analog computing information.

14. The memory apparatus of claim 13, wherein the processing circuit comprises:
a control circuit coupled to the semiconductor device, and configured to control the semiconductor device to perform the first operation;
an analog-to-digital conversion circuit coupled to the semiconductor device, and configured to convert the analog computing information into digital information; and
a data processing circuit coupled to the analog-to-digital conversion circuit, and configured to perform a second operation on the digital information to determine the operation result.

15. A method of controlling a semiconductor device, comprising:
applying a first read voltage to a word line coupled to one first memory cell of a plurality of first memory cells of a memory string, applying a first pass voltage to a first portion of word lines, and applying a second pass voltage to a second portion of word lines after performing a program operation on the plurality of first memory cells, wherein the second pass voltage is different from the first pass voltage; and
acquiring a current on a signal line coupled to one end of the memory string, wherein the current on the memory string is within a target current range,
wherein the semiconductor device includes a memory cell array including a plurality of memory strings, one memory string of the plurality of memory strings includes a plurality of first memory cells and a plurality of second memory cells connected, and word lines coupled to the plurality of second memory cells include the first portion of word lines and the second portion of word lines.

16. The method of claim 15, wherein:
the plurality of second memory cells of the plurality of memory strings are configured to have a program state and an erase state, and
the method further comprises:
acquiring a ratio of a number of the second memory cells in the erase state to the number of the second memory cells in the program state in the first portion of word lines that is a first ratio;
acquiring a ratio of the number of the second memory cells in the erase state to the number of the second memory cells in the program state in the second portion of word lines that is a second ratio; and
applying the first pass voltage to the first portion of word lines, and applying the second pass voltage to the second portion of word lines, wherein the first ratio is greater than the second ratio, and the first pass voltage is less than the second pass voltage.

17. The method of claim 15, wherein:
the word lines coupled to the plurality of second memory cells further include a third portion to an N-th portion, wherein N is a positive integer greater than or equal to 3, and
the method comprises:
applying different pass voltages to different portions of word lines.

18. The method of claim 15, comprising:
performing a program operation on at least part of the second memory cells in an erase state on the memory string in response to the current on the memory string not being within the target current range,
wherein, in different portions of word lines, ratios of a number of the second memory cells in the erase state to the number of the second memory cells in a program state are different.

19. The method of claim 15, comprising:
applying a second read voltage to a word line coupled to one first memory cell of the plurality of first memory cells of the memory string, keeping applying a pass voltage in a case of a current being within the target current range to the first portion of word lines, and keeping applying a pass voltage in a case of a current being within the target current range to the second portion of word lines, in response to the current on the memory string being within the target current range; and
acquiring the current on the signal line coupled to the one end of the memory string to obtain analog computing information.

20. The method of claim 19, comprising:
during a period of applying a second read voltage to a word line coupled to the one first memory cell of the first memory cells of the memory string, applying a first turn-on voltage to word lines coupled to remaining first memory cells of the first memory cells, and applying a second turn-on voltage to a top select gate line coupled to the memory string, to acquire the current on the signal line coupled to the one end of the memory string.
